(19) United States
(12) Patent Application Publication
(10) Pub. No.: US 2026/0020420 A1
(43) Pub. Date: Jan. 15, 2026

(54) SEMICONDUCTOR STRUCTURE, SEMICONDUCTOR UNIT, AND FORMATION METHOD THEREOF

(71) Applicant: Lextar Electronics Corporation, Hsinchu City (TW)

(72) Inventors: Shiou-Yi KUO, Hsinchu City (TW); Chih-Hao LIN, Hsinchu City (TW)

(21) Appl. No.: 19/268,741

(22) Filed: Jul. 14, 2025

(30) Foreign Application Priority Data
Jul. 15, 2024 (TW) 113126398

(51) Int. Cl. H10H 29/85; H10H 20/824; H10H 29/01; H10H 29/03

(52) U.S. Cl. CPC H10H 29/857; H10H 20/824; H10H 29/0364; H10H 29/03

(57) ABSTRACT

A semiconductor structure, a semiconductor unit, and a formation method thereof are provided. The semiconductor structure includes a underlying layer, a supporting member, and a semiconductor device. The underlying layer has a protruding portion. The supporting member is disposed on the underlying layer. The supporting member includes a bonding portion, a connecting portion, and a carrying portion. The bonding portion is connecting to the protruding portion of the underlying layer. The connecting portion is located next to the bonding portion. The carrying portion is located next to the connecting portion. The semiconductor device is disposed on the carrying portion and exposes the bonding portion and the connecting portion. There is a gap between the carrying portion of the supporting member and the underlying layer.

### CROSS REFERENCE TO RELATED APPLICATIONS

This application claims priority of Taiwan Patent Application No. TW 113126398, filed on Jul. 15, 2024, the content of the entirety of which is incorporated by reference herein.

### TECHNICAL FIELD

Some embodiments of the present disclosure relate to a semiconductor structure, a semiconductor unit, and a formation method thereof, and, in particular, they relate to a semiconductor structure including a supporting member, a semiconductor unit including a supporting member, and a formation method thereof.

### BACKGROUND

With the advancement of technology, various electronic products are developing in such a way to become lighter, thinner, shorter, and smaller. The size of the semiconductor components (for example, light-emitting diodes (LEDs) or integrated circuits (ICs)) used therein is also shrinking accordingly, and the related process technologies (for example, the mass transfer processes) and cost requirements may become even higher.

Although existing semiconductor structures, semiconductor units, and their forming methods have gradually met their intended uses, they still have not thoroughly satisfied the requirements in all respects. Accordingly, there are still some issues to be overcome regarding the semiconductor structures, semiconductor units, and their forming methods.

### SUMMARY

In some embodiments, a semiconductor structure is provided. The semiconductor structure includes a underlying layer, a supporting member, and a semiconductor device. The underlying layer has a protruding portion. The supporting member is disposed on the underlying layer. The supporting member includes a bonding portion, a connecting portion, and a carrying portion. The bonding portion is connecting to the protruding portion of the underlying layer. The connecting portion is located next to the bonding portion. The carrying portion is located next to the connecting portion. The semiconductor device is disposed on the carrying portion and exposes the bonding portion and the connecting portion. There is a gap between the carrying portion of the supporting member and the underlying layer.

In some embodiments, a semiconductor unit is provided. The semiconductor unit includes a supporting member and a semiconductor device. The supporting member includes a connecting portion and a carrying portion. The connecting portion has a first side surface. The carrying portion is located next to the connecting portion and has a second side surface. The semiconductor device is disposed on the carrying portion and exposes the connecting portion. A roughness of the first side surface is greater than a roughness of the second side surface.

In some embodiments, a method for forming a semiconductor structure is provided. The formation method includes providing a underlying layer. The formation method includes forming an insulating layer on the underlying layer. The formation method includes forming a semiconductor device on the insulating layer. The formation method includes patterning the insulating layer to form a supporting member. The formation method includes removing a portion of the underlying layer so that there is a gap between a bottom surface of the supporting member and a top surface of the underlying layer.

The semiconductor structure, the semiconductor unit, and the formation method thereof of the present disclosure may be applied in various types of electronic apparatus. In order to make the features and advantages of some embodiments of the present disclosure more understanding, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIGS. 1 to 4 are schematic cross-sectional views of different stages of a method for forming a semiconductor structure 1 according to some embodiments of the present disclosure.

FIG. 5 is a detailed schematic cross-sectional view of a semiconductor structure 1 according to some embodiments of the present disclosure.

FIG. 6 is a partial schematic top view of a semiconductor structure 1 according to some embodiments of the present disclosure.

FIG. 7 is a schematic cross-sectional view of a semiconductor unit 1′ according to some embodiments of the present disclosure.

FIG. 8 is a schematic top view of a semiconductor unit 1′ according to some embodiments of the present disclosure.

FIG. 9 is a schematic top view of a semiconductor structure 2 according to some embodiments of the present disclosure.

FIG. 10 is a schematic top view of a semiconductor unit 2′ according to some embodiments of the present disclosure.

FIGS. 11 to 16 are schematic cross-sectional views of different stages of a method for forming a semiconductor structure 3 according to some embodiments of the present disclosure.

FIG. 17 is a detailed schematic cross-sectional view of a semiconductor structure 3 according to some embodiments of the present disclosure.

FIG. 18 is a partial schematic top view of a semiconductor structure 3 according to some embodiments of the present disclosure.

FIG. 19 is a schematic cross-sectional view of a semiconductor unit 3′ according to some embodiments of the present disclosure.

FIG. 20 is a schematic top view of a semiconductor unit 3′ according to some embodiments of the present disclosure.

FIG. 21 is a detailed schematic cross-sectional view of a semiconductor structure 4 according to some embodiments of the present disclosure.

### DETAILED DESCRIPTION

Semiconductor structures, semiconductor units, and formation methods of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first element is located on or over a second element, it may include the embodiment which the first element and the second element are in direct contact and the embodiment which the first element and the second element are not in direct contact with each other, that is one or more other elements is between the first element and the second element. However, if the first element is directly on the second element, it means that the first element and the second element are in direct contact.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The term “a range between a first value and a second value” or “a first value˜a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art may refer to the same element by different terms. The present disclosure does not intend to distinguish between elements that have the same function but with different terms. In the following description and claims, terms such as “including”, “containing”, and “having” are open-ended words, so they should be interpreted as meaning “including but not limited to . . . ”. Therefore, when the terms “including”, “containing”, and/or “having” is used in the description of the present disclosure, it designates the presence of corresponding features, regions, steps, operations, and/or elements, but does not exclude the presence of one or more corresponding features, regions, steps, operations, and/or elements.

It should be understood that, in the embodiments illustrated below, without departing from the spirit of the present disclosure, components in multiple different embodiments can be replaced, reorganized, and combined to complete other embodiments. Components in various embodiments can be used in any combination as long as they do not violate the spirit of the disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For ease of description, hereinafter, the X-axis is a first direction D1 (in the width direction), the Y-axis is a second direction D2 (in the length direction), and the Z-axis is a third direction D3 (in the thickness/depth direction). In some embodiments, the schematic cross-sectional views of the present disclosure are schematic cross-sectional views observing the XZ plane, and the schematic top views of the present disclosure are schematic top views observing the XY plane. In some embodiments, the third direction D3 may be a normal direction of the first semiconductor layer.

In some embodiments, the term “a distance between first element and second element” means that the distance is between a center of first element and a center of second element, or the distance is between a boundary of first element and a boundary of second element. Wherein, the center of the element may be the geometric center of the element.

In some embodiments, the term “roughness” may be average roughness, maximum roughness, ten-point average roughness, or other roughness calculated by other suitable method.

In some embodiments, additional components may be added to the semiconductor element of the present disclosure. In some embodiments, some components of the semiconductor element of the present disclosure may be replaced or omitted. In some embodiments, additional operational steps may be provided before, during, and/or after the method of manufacturing the semiconductor element. In some embodiments, some of the operational steps may be replaced or omitted, and the order of some of the operational steps is interchangeable. Furthermore, it should be understood that some of the operational steps may be replaced or deleted for other embodiments of the method. Furthermore, in the present disclosure, the number and size of each component in the drawings are only for illustration and are not used to limit the scope of the present disclosure.

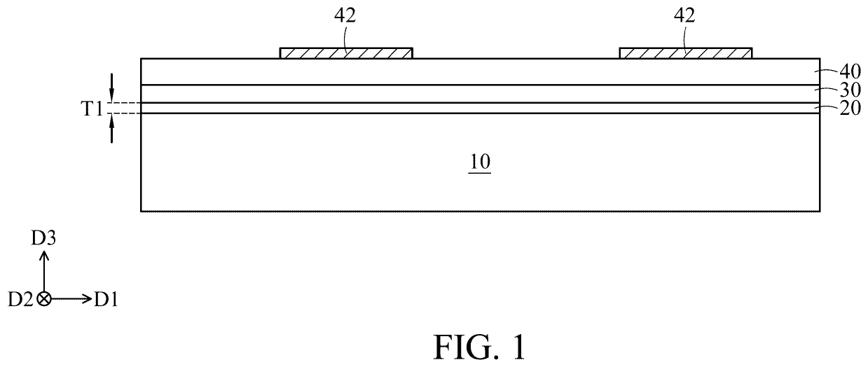

Referring to FIG. 1, it is a schematic cross-sectional view of different stages of a method for forming a semiconductor structure according to some embodiments of the present disclosure. As shown in FIG. 1, in some embodiments, a first semiconductor layer 10 may be provided. In some embodiments, the first semiconductor layer 10 may include an elemental semiconductor, a compound semiconductor, an alloy semiconductor, the like, or a combination thereof. In some embodiments, the elemental semiconductor may include silicon (Si) or germanium (Ge). In some embodiments, the compound semiconductor may include a III-V semiconductor material, for example, gallium nitride (GaN), aluminum gallium nitride (AlGaN), aluminum indium nitride (AlInN), indium gallium nitride (InGaN), indium aluminum gallium nitride (InAlGaN), gallium arsenide (GaAs), gallium phosphide (GaP), indium phosphide (InP), indium arsenide (InAs), indium antimonide (InSb), the like, or a combination thereof. In some embodiments, the compound semiconductor may include silicon carbide (SiC). In some embodiments, the alloy semiconductor may include SiGe, the like, or a combination thereof.

As shown in FIG. 1, in some embodiments, an insulating layer 20 may be formed on the first semiconductor layer 10. In some embodiments, the insulating layer 20 may include an oxide such as silicon oxide, a nitride such as silicon nitride, an oxynitride such as silicon oxynitride, the like, or a combination thereof, but the present disclosure is not limited thereto. In some embodiments, the insulating layer 20 may be formed by performing a plasma process such as oxygen plasma process on the first semiconductor layer 10. For example, the first semiconductor layer 10 may be silicon, and the insulating layer 20 may be silicon oxide formed by performing an oxygen plasma process on silicon.

As shown in FIG. 1, in some embodiments, in the normal direction of the first semiconductor layer 10 (that is, the third direction D3), the insulating layer 20 may have a first thickness T1. In some embodiments, the first thickness T1 may be 2 um˜3 um. For example, the first thickness T1 may be 2 um, 2.1 um, 2.2 um, 2.3 um, 2.4 um, 2.5 um, 2.6 um, 2.7 um, 2.8 um, 2.9 um, 3 um, or any value or any range of values between the aforementioned values, but the present disclosure is not limited thereto.

As shown in FIG. 1, in some embodiments, a second semiconductor layer 30 may be formed on the insulating layer 20, such that the insulating layer 20 is between the first semiconductor layer 10 and the second semiconductor layer 30. In some embodiments, the material of the second semiconductor layer 30 may be the same as or different from the material of the first semiconductor layer 10. In some embodiments, the second semiconductor layer 30 may include a III-V semiconductor material. In some embodiments, the first semiconductor layer 10 and the second semiconductor layer 30 may have the same material, and the insulating layer 20 may serve as a buried insulating layer interposed between them. For example, the first semiconductor layer 10 and the second semiconductor layer 30 may both be silicon. In some embodiments, the first semiconductor layer 10, the insulating layer 20, and the second semiconductor layer 30 may collectively serve as a silicon-on-insulator (SOI) structure, but the present disclosure is not limited thereto.

As shown in FIG. 1, in some embodiments, an device layer 40 may be formed on the second semiconductor layer 30. In some embodiments, the device layer 40 may include a conductive material, a semiconductor material, and/or an insulating material, but the present disclosure is not limited thereto. In some embodiments, the conductive material may include a metal, a conductive nitride, a conductive oxide, the like, or a combination thereof, but the present disclosure is not limited thereto. In some embodiments, the metal is, for example, tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), alloys thereof, or a combination thereof, but the present disclosure is not limited thereto. In some embodiments, the conductive nitride may include titanium nitride (TiN), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), the like, or a combination thereof, but the present disclosure is not limited thereto. In some embodiments, the conductive oxide may be a transparent conductive oxide (TCO), and may include indium tin oxide (ITO), aluminum zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), the like, or a combination thereof, but the present disclosure is not limited thereto. In some embodiments, the semiconductor material may include a III-V semiconductor material, for example, a III nitride, a III phosphide, a III arsenide, the like, or a combination thereof, but the present disclosure is not limited thereto. In some embodiments, the insulating material may include dielectric oxide, dielectric nitride, dielectric oxynitride, the like, or a combination thereof, but the present disclosure is not limited thereto. As shown in FIG. 1, in some embodiments, a contact pad 42 may be formed on the device layer 40. In some embodiments, the material of the contact pad 42 may include a metal, a conductive nitride, a conductive oxide, the like, or a combination thereof, but the present disclosure is not limited thereto. In some embodiments, the metal is, for example, tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), alloys thereof, or a combination thereof, but the present disclosure is not limited thereto. In some embodiments, the conductive nitride may include titanium nitride (TiN), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), the like, or a combination thereof, but the present disclosure is not limited thereto. In some embodiments, the conductive oxide may be a transparent conductive oxide (TCO), and may include indium tin oxide (ITO), aluminum zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), the like, or a combination thereof, but the present disclosure is not limited thereto.

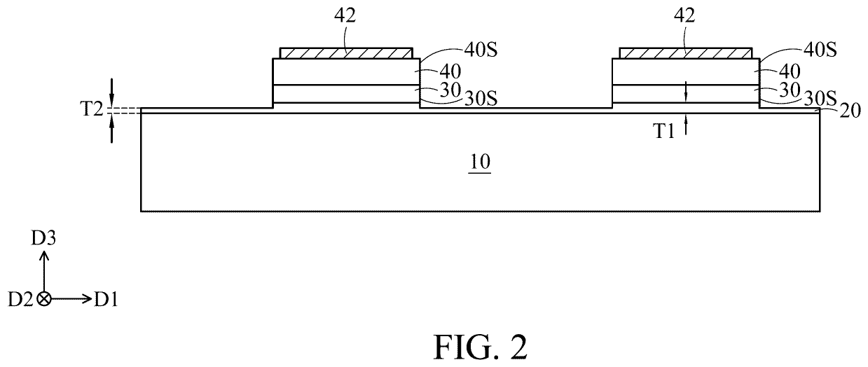

Referring to FIG. 2, it is a schematic cross-sectional view of different stages of a method for forming a semiconductor structure according to some embodiments of the present disclosure. As shown in FIG. 2, in some embodiments, a removal process may be performed to remove a portion of the device layer 40 and a portion of the second semiconductor layer 30, thereby exposing the top surface of the insulating layer 20. In some embodiments, after the removal process is performed, the side surface 30S of the second semiconductor layer 30 may be aligned with the side surface 40S of the device layer 40.

In some embodiments, the removal process may include an etching process or other suitable process, but the present disclosure is not limited thereto. In some embodiments, the etching process may include dry etching, wet etching, or a combination thereof. In some embodiments, the dry etching may include plasma etching, plasma-free etching, sputter etching, ion milling, and reactive ion etching (RIE). In some embodiments, the wet etching may include using an acidic solution, an alkaline solution, or a solvent. For example, a portion of the device layer 40 and a portion of the second semiconductor layer 30 may be removed by performing a plasma process.

In some embodiments, the step of removing a portion of the device layer 40 and a portion of the second semiconductor layer 30 may further include removing a portion of the insulating layer 20. In other words, a removal process may be performed to remove a portion of the device layer 40, a portion of the second semiconductor layer 30, and a portion of the insulating layer 20. In some embodiments, a second thickness T2 of the insulating layer 20 exposed after the removal process may be less than a first thickness T1 of the insulating layer 20 covered by the device layer 40 and the second semiconductor layer 30. In other words, the second thickness T2 of the exposed insulating layer 20 may be less than the first thickness T1 of the insulating layer 20 located right below the second semiconductor layer 30.

In some embodiments, the second thickness T2 may be 1 um˜2 um. For example, the second thickness T2 may be 1 um, 1.1 um, 1.2 um, 1.3 um, 1.4 um, 1.5 um, 1.6 um, 1.7 um, 1.8 um, 1.9 um, 2 um, or any value or any range of values between the aforementioned values, but the present disclosure is not limited thereto. Accordingly, when the second thickness T2 is less than 1 um, the supporting strength and reliability of the subsequently formed supporting member will be insufficient. When the second thickness T2 is greater than 2 um, it will be difficult to perform the subsequent separation process.

As shown in FIG. 1 and FIG. 2, in some embodiments, the second semiconductor layer 30 and the device layer 40 may together forms a semiconductor device. Therefore, the semiconductor device may be formed on the insulating layer 20 by sequentially forming the second semiconductor layer 30 and the device layer 40 on the insulating layer 20, and removing a portion of the device layer 40 and a portion of the second semiconductor layer 30. In some embodiments, the semiconductor device may be an integrated circuit (IC). In other embodiments, the second semiconductor layer 30 may be omitted, so that the device layer 40 is used as a semiconductor device.

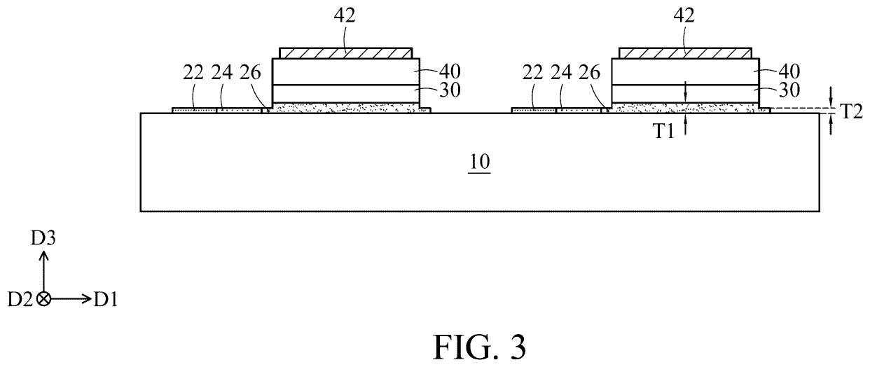

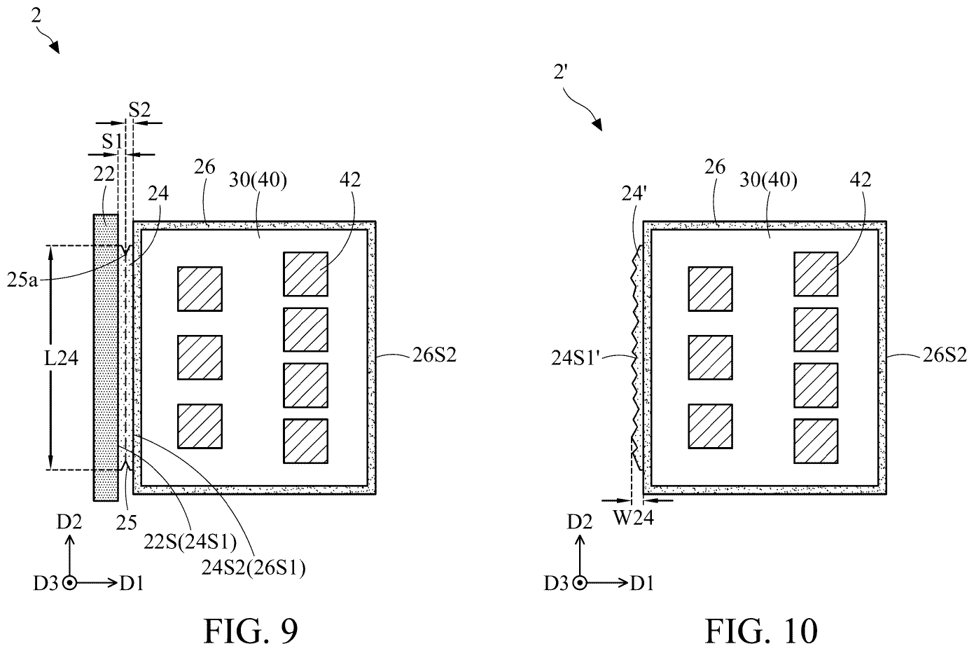

Referring to FIG. 3, it is a schematic cross-sectional view of different stages of a method for forming a semiconductor structure according to some embodiments of the present disclosure. As shown in FIG. 3, in some embodiments, the insulating layer 20 may be patterned to form a supporting member 21 on the first semiconductor layer 10. In some embodiments, the insulating layer 20 may be patterned by a removal process. In some embodiments, after patterning the insulating layer 20, a portion of the first semiconductor layer 10 may be exposed. In some embodiments, the insulating layer 20 may be patterned to form a recess (for example, the recess 25 shown in the subsequent FIG. 9) in the insulating layer 20. Accordingly, since the insulating layer 20 may be the buried insulating layer in the SOI structure, and the supporting member 21 may be formed by patterning the insulating layer 20, that is, there is no need to deposit other materials as the supporting member, thus reducing the process steps, and improving the process yield and/or reliability.

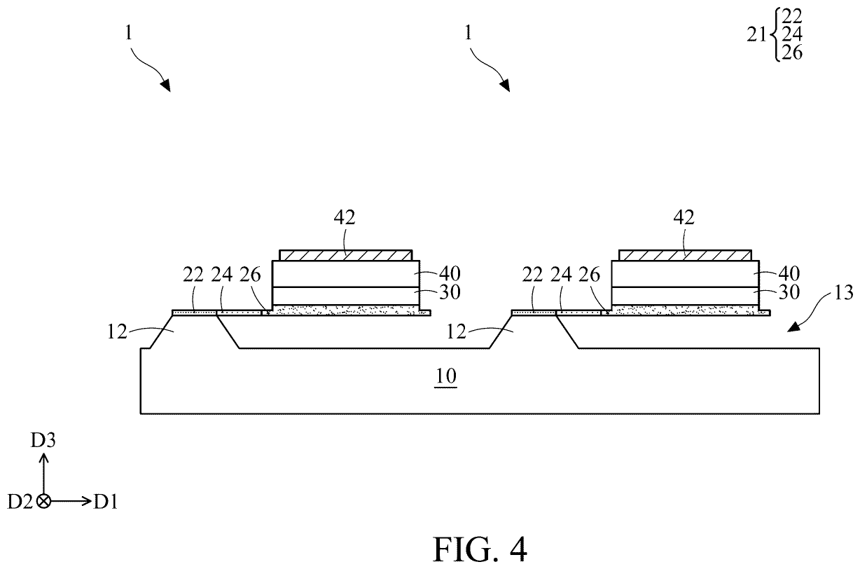

Referring to FIG. 4, it is a schematic cross-sectional view of different stages of a method for forming a semiconductor structure 1 according to some embodiments of the present disclosure. As shown in FIG. 4, in some embodiments, a removal process may be performed to remove a portion of the first semiconductor layer 10, so that a portion of the first semiconductor layer 10 is separated from the supporting member 21, thereby obtaining the semiconductor structure 1. Specifically, a portion of the first semiconductor layer 10 below the device layer 40 may be removed to form a protruding portion 12 and a cavity 13 adjacent to each other between the first semiconductor layer 10 and the supporting member 21. In addition, the protruding portion 12 may be connected to the supporting member 21, and the cavity 13 overlap the device layer 40 in the vertical direction (for example, the third direction D3).

In some embodiments, in a cross-sectional view, the protruding portion 12 may have a regular trapezoid, an inverted trapezoid, a rectangle, or other similar shapes. In some embodiments, the cavity 13 may include air, an inert gas, the like, or a combination thereof, or the cavity 13 may be a vacuum.

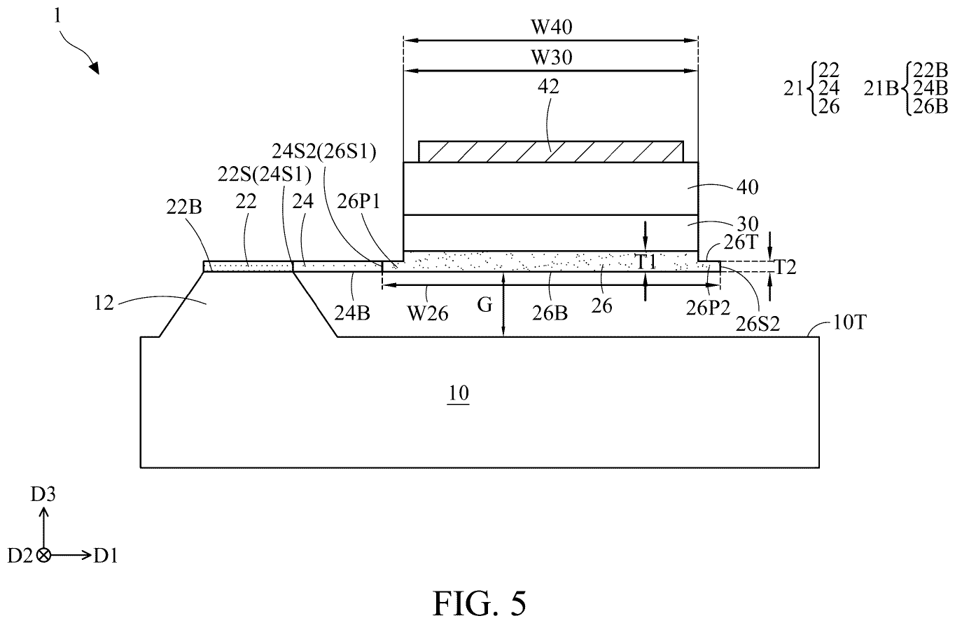

Referring to FIG. 5, it is a detailed schematic cross-sectional view of the semiconductor structure 1 according to some embodiments of the present disclosure. As shown in FIG. 5, in some embodiments, the supporting member 21 may be located on the protruding portion 12 of the first semiconductor layer 10. In some embodiments, in the first direction D1, the supporting member 21 may include a bonding portion 22, a connecting portion 24, and a carrying portion 26 arranged in sequence. In some embodiments, the bonding portion 22 may be disposed on the protruding portion 12 of the first semiconductor layer 10 so as to be connected thereto. In some embodiments, the connecting portion 24 may be located between the bonding portion 22 and the carrying portion 26. In some embodiments, the second semiconductor layer 30 and the device layer 40 may be located on the carrying portion 26. In other words, the second semiconductor layer 30 may be located between the carrying portion 26 and the device layer 40. In some embodiments, the second semiconductor layer 30 and the device layer 40 may expose the bonding portion 22 and the connecting portion 24. In other words, the second semiconductor layer 30 and the device layer 40 may not be located on the bonding portion 22 and the connecting portion 24.

As shown in FIG. 5, in some embodiments, a gap G may be formed between the bottom surface 24B of the connecting portion 24 and the top surface 10T of the first semiconductor layer 10, and the gap G may be provided between the bottom surface 26B of the carrying portion 26 and the top surface 10T of the first semiconductor layer 10. In some embodiments, in the third direction D3, the depth of the gap G below the carrying portion 26 may be a constant value. In some embodiments, in the third direction D3, the depth of the gap G below the connecting portion 24 may gradually decrease along the first direction D1 toward the protruding portion 12. In some embodiments, the bottom surface 22B of the bonding portion 22 may be parallel to the top surface 10T of the first semiconductor layer 10. In some embodiments, in a cross-sectional view, the top surface 10T of the first semiconductor layer 10 may be level, U-shaped, V-shaped, or other similar profiles.

As shown in FIG. 5, in some embodiments, the second semiconductor layer 30 and the device layer 40 may expose a portion 26P1 and 26P2 of the carrying portion 26. In some embodiments, the second thickness T2 of the portion 26P1 and 26P2 of the carrying portion 26 exposed by the second semiconductor layer 30 and the device layer 40 may be less than the first thickness T1 of the other portion (remaining portion) of the carrying portion 26 located below the second semiconductor layer 30 and the device layer 40. In some embodiments, in the first direction D1, the second semiconductor layer 30 may have a width W30, the device layer 40 may have a width W40, and the width W30 and the width W40 may be substantially the same. In the first direction D1, the carrying portion 26 may have a width W26, and the width W26 may be greater than the width W30 and the width W40.

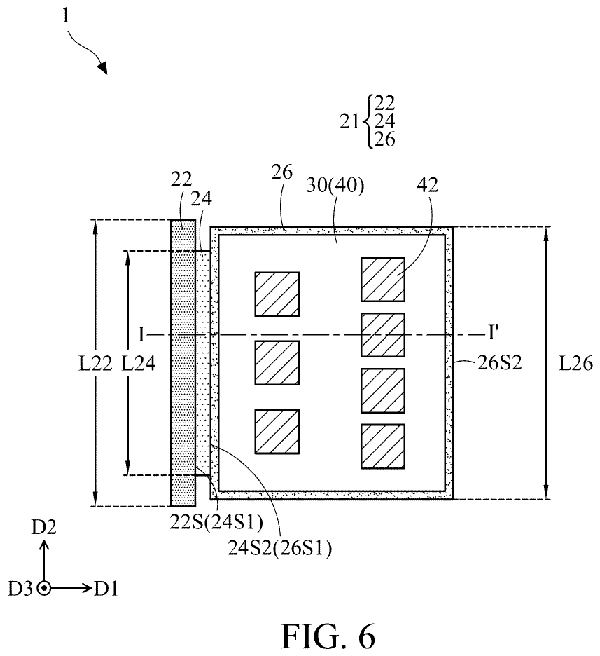

Referring to FIG. 6, it is a partial top view of a semiconductor structure 1 according to some embodiments of the present disclosure, and the cross-sectional view shown in FIG. 5 is a cross-sectional view taken along line segment I-I′ of FIG. 6. In some embodiments, along the first direction D1, the connecting portion 24 may have side surfaces 24S1 and 24S2 opposite to each other. In some embodiments, along the first direction D1, the carrying portion 26 may have side surfaces 26S1 and 26S2 opposite to each other. In some embodiments, the side surface 22S of the bonding portion 22 may be located next to the side surface 24S1 of the connecting portion 24, and the side surface 24S2 of the connecting portion 24 may be located next to the side surface 26S1 of the carrying portion 26. In some embodiments, in the second direction D2, the length L24 of the connecting portion 24 may be less than the length L22 of the bonding portion 22. In some embodiments, in the second direction D2, the length L24 of the connecting portion 24 may be less than the length L26 of the carrying portion 26. Accordingly, by adjusting the length of the connecting portion 24, the subsequent separation process is facilitated.

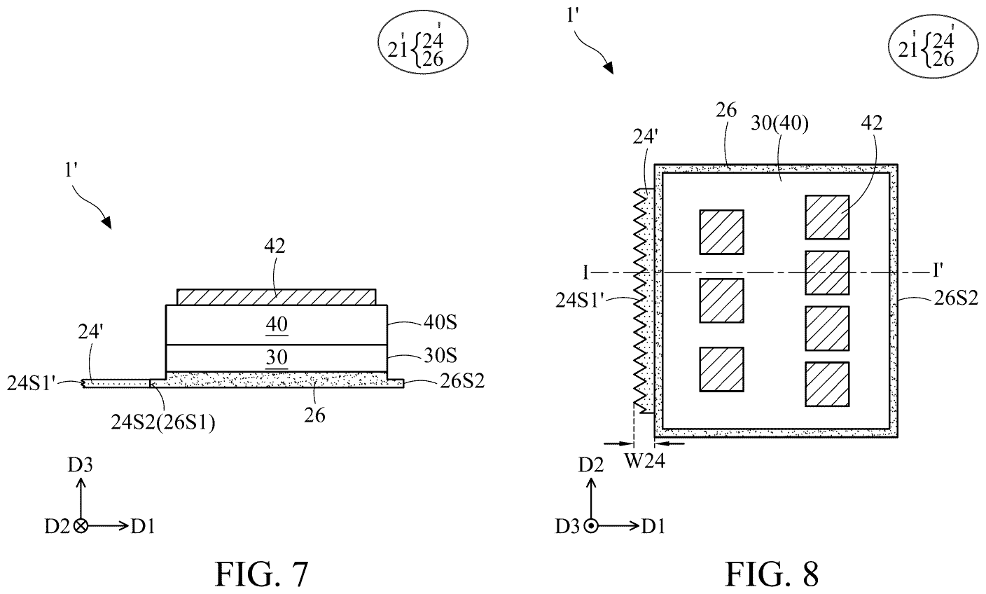

Referring to FIGS. 7 and 8, which are respectively a schematic cross-sectional view and a schematic top view of a semiconductor unit 1′ according to some embodiments of the present disclosure. In some embodiments, a separation process may be performed on the semiconductor structure 1 to form a semiconductor unit 1′. In some embodiments, the separation process may be a stamp pick up process. In some embodiments, a stamp may be applied to the semiconductor structure 1 to break the supporting member 21 and pick up the semiconductor unit 1′. Therefore, a plurality of semiconductor units 1′ may be transferred to other carriers along with the stamp, thereby achieving mass transfer.

As shown in FIGS. 7 and 8, in some embodiments, the bonding portion 22 and the connecting portion 24 may be separated by performing a separation process. For example, the bonding portion 22 and the connecting portion 24 may be disconnected by applying an external force such as pressing down. Accordingly, after performing the separation process, the supporting member 21′ of the semiconductor unit 1′ may include a connecting portion 24′ and the carrying portion 26. In some embodiments, after performing the separation process, the roughness of the side surface 24S1′ of the connecting portion 24 may be greater than the roughness of the side surface 26S2 of the carrying portion 26. In other words, the roughness of one side surface of the supporting member 21′ may be greater than the roughness of the other side surface of the supporting member 21′.

Hereinafter, the same or similar reference numerals and descriptions are omitted.

Referring to FIGS. 9 and 10, which are schematic cross-sectional views of a semiconductor structure 2 and a semiconductor unit 2′ according to some embodiments of the present disclosure. in some embodiments, a separation process may be performed on the semiconductor structure 2 to obtain the semiconductor unit 2′.

As shown in FIG. 9, in some embodiments, in a top view, the connecting portion 24 may have a recess 25. Specifically, in a top view, the recess 25 dents inwardly along the second direction D2 from an edge of the connecting portion 24. In some embodiments, the recess 25 may be formed by the step of patterning the insulating layer 20 as shown in FIG. 3. In some embodiments, the recess 25 of the connecting portion 24 may be formed by using a mask having a specific pattern. Accordingly, by forming the recess 25, the area of the connecting portion 24 may be reduced, thereby facilitating the separation process. In detail, the recess 25 may serve as a stress concentration point in the connecting portion 24, thereby facilitating stress release. In some embodiments, the length L24 of the connecting portion 24 in the second direction D2 may not be a constant value. In some embodiments, in a top view, the recess 25 may be V-shaped, U-shaped, or other similar profiles. In some embodiments, a first distance S1 may be provided between the innermost point 25a of the recess 25 and the side surface 24S1 of the connecting portion 24 along the first direction D1, a second distance S2 may be provided between the innermost point 25a of the recess 25 and the side surface 24S2 of the connecting portion 24 along the first direction D1, and the first distance S1 may be greater than or equal to the second distance S2. Accordingly, by adjusting the location of the innermost point 25a of the recess 25, the length L24 of the connecting portion 24 may be shorter to make the separation process easily. Furthermore, by adjusting the location of the innermost point 25a of the recess 25, the area of the connecting portion 24′ may be reduced after the separation process is performed, thereby reducing the size of the semiconductor unit 2′.

As shown in FIG. 10, in some embodiments, the width W24 of the connecting portion 24′ of the semiconductor unit 2′ may be smaller than the width W24 of the connecting portion 24′ of the semiconductor unit 1′. In some embodiments, the width W24 of the connecting portion 24′ of the semiconductor unit 2′ may be greater than or equal to 0.

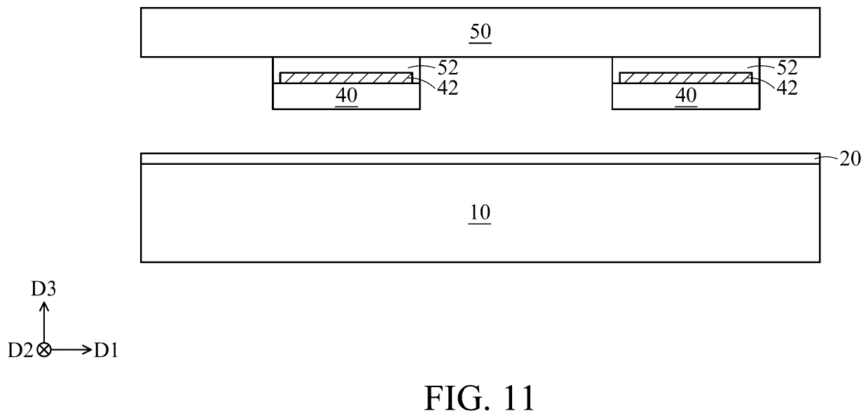

Referring to FIG. 11, it is a schematic cross-sectional view of different stages of a method for forming a semiconductor structure according to some embodiments of the present disclosure. As shown in FIG. 11, in some embodiments, a first semiconductor layer 10 may be provided, and an insulating layer 20 may be formed on the first semiconductor layer 10.

As shown in FIG. 11, in some embodiments, a carrier 50 may be provided. In some embodiments, the carrier 50 may include silicon, glass, sapphire, ceramic, polyimide (PI), polycarbonate (PC), polyethylene terephthalate (PET), polypropylene (PP), the like, or a combination thereof, but the present disclosure is not limited thereto. In some embodiments, a first adhesive layer 52 may be formed on the carrier 50. In some embodiments, the first adhesive layer 52 may include a thermal-release adhesive, an ultraviolet (UV)-release adhesive, a light-to-heat conversion (LTHC) adhesive, other suitable release-type adhesive layers, or a combination thereof, but the present disclosure is not limited thereto.

As shown in FIG. 11, in some embodiments, the device layer 40 may be formed on the first adhesive layer 52. In some embodiments, before forming the device layer 40 on the first adhesive layer 52, a contact pad 42 may be formed on the device layer 40. In some embodiments, the device layer 40 and the contact pad 42 may contact the first adhesive layer 52. In some embodiments, the contact pad 42 may be embedded in the first adhesive layer 52.

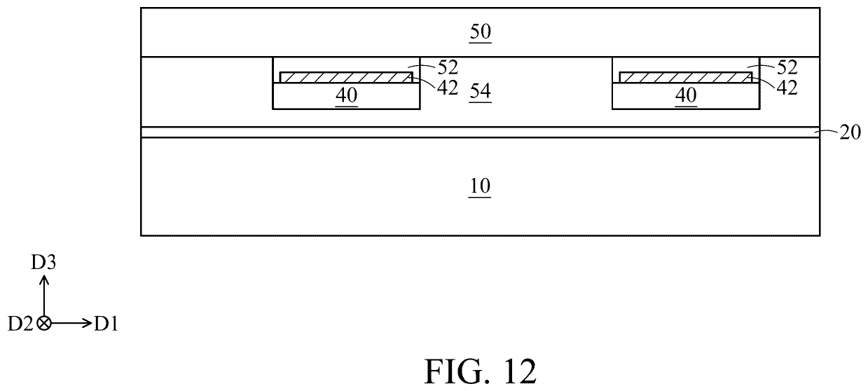

Referring to FIG. 12, it is a schematic cross-sectional view of different stages of a method for forming a semiconductor structure according to some embodiments of the present disclosure. As shown in FIG. 12, in some embodiments, a second adhesive layer 54 may be formed on the device layer 40 and/or on the insulating layer 20 to bond the device layer 40 with the insulating layer 20. In some embodiments, after the device layer 40 and the insulating layer 20 are bonded, the device layer 40, the contact pad 42, and the first adhesive layer 52 may be embedded in the second adhesive layer 54. In some embodiments, the second adhesive layer 54 may contact the device layer 40, the first adhesive layer 52, and the carrier 50. In some embodiments, the material of the second adhesive layer 54 and the material of the first adhesive layer 52 may be the same or different. In some embodiments, since the device layer 40 may be used as a semiconductor device, the semiconductor device may be formed on the insulating layer 20 by the second adhesive layer 54. In some embodiments, the semiconductor device may be an integrated circuit (IC) or a light-emitting diode (LED).

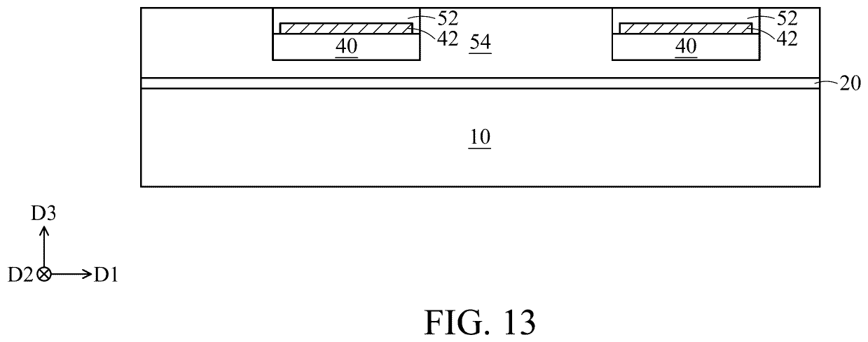

Referring to FIG. 13, it is a schematic cross-sectional view of different stages of a method for forming a semiconductor structure according to some embodiments of the present disclosure. As shown in FIG. 13, in some embodiments, the carrier 50 may be removed to expose the first adhesive layer 52 and the second adhesive layer 54. In some embodiments, the carrier 50 may be removed from the first adhesive layer 52 and the second adhesive layer 54 by irradiating the first adhesive layer 52 and the second adhesive layer 54 with the same laser.

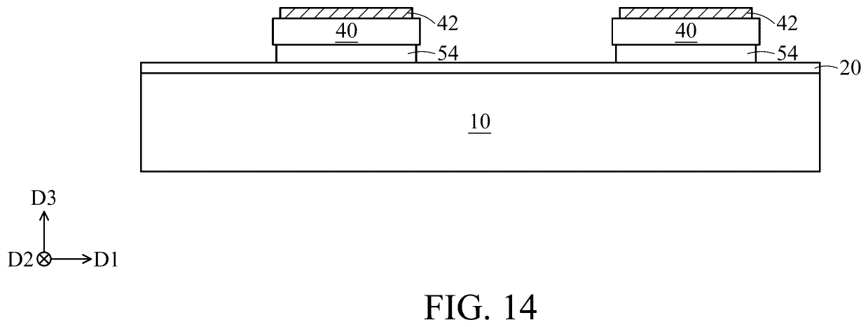

Referring to FIG. 14, it is a schematic cross-sectional view of different stages of a method for forming a semiconductor structure according to some embodiments of the present disclosure. As shown in FIG. 14, in some embodiments, the first adhesive layer 52 and a portion of the second adhesive layer 54 may be removed to pattern the second adhesive layer 54. In some embodiments, patterning the second adhesive layer 54 may expose the top surface of the insulating layer 20. In some embodiments, during the process of patterning the second adhesive layer 54, a portion of the second adhesive layer 54 located below and near the peripheral of the device layer 40 may be removed, and the other portion of the second adhesive layer 54 located below the device layer 40 may be remained. That is, the remaining portion of the second adhesive layer 54 is covered by the device layer 40 and indenting from the edge of the device layer 40.

As shown in FIG. 14, in some embodiments, the second adhesive layer 54 may be patterned by performing a plasma process. In some embodiments, the thickness of the insulating layer 20 exposed by patterning the second adhesive layer 54 may be the same as or different from the thickness before being exposed. For example, when a plasma process such as oxygen plasma is used to remove the first adhesive layer 52 and the second adhesive layer 54, the thickness of the insulating layer 20 exposed after removing the second adhesive layer 54 may not change. When a plasma process such as fluorine plasma is used to remove the first adhesive layer 52 and the second adhesive layer 54, the thickness of the insulating layer 20 exposed after removing the second adhesive layer 54 may decrease. Thus, similar to FIG. 2, the insulating layer 20 covered by the second adhesive layer 54 may have a first thickness T1, and the insulating layer 20 exposed by the second adhesive layer 54 may have a second thickness T2, and the first thickness T1 may be greater than the second thickness T2.

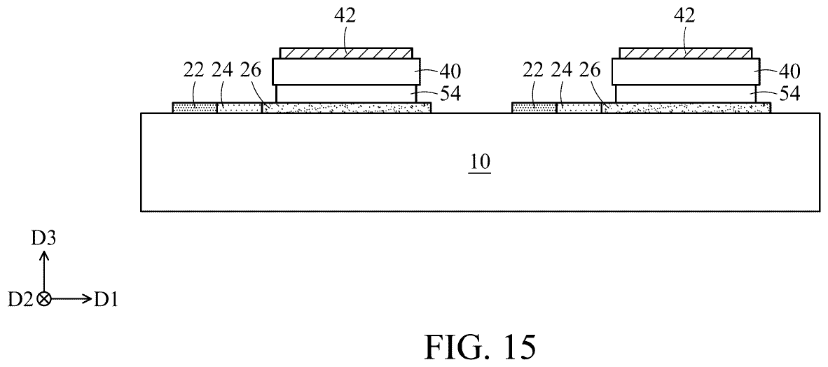

Referring to FIG. 15, it is a schematic cross-sectional view of different stages of a method for forming a semiconductor structure according to some embodiments of the present disclosure. As shown in FIG. 15, in some embodiments, the insulating layer 20 may be patterned to form a supporting member 21.

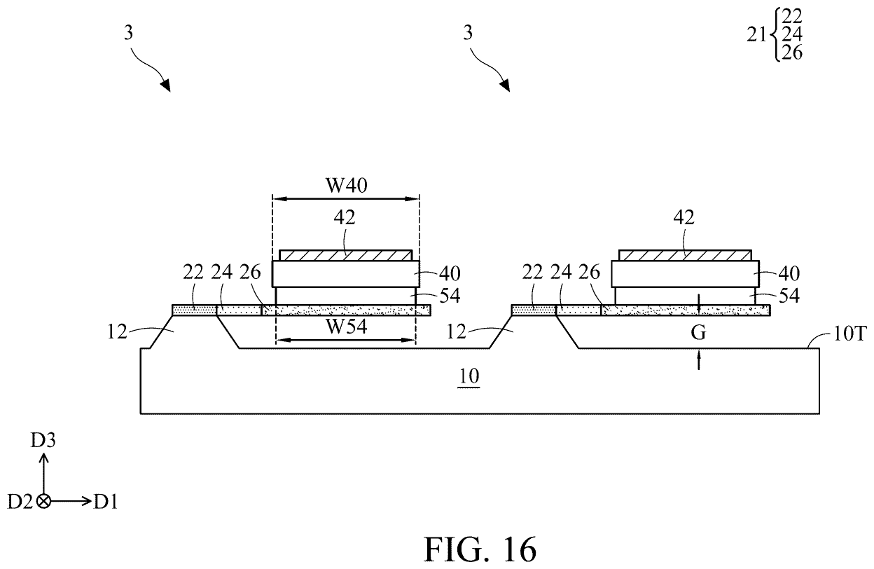

Referring to FIG. 16, it is a schematic cross-sectional view of different stages of a method for forming a semiconductor structure according to some embodiments of the present disclosure. As shown in FIG. 16, in some embodiments, a portion of the first semiconductor layer 10 may be removed, so that a gap G may be between the supporting member 21 and the top surface 10T of the first semiconductor layer 10, thereby obtaining a semiconductor structure 3.

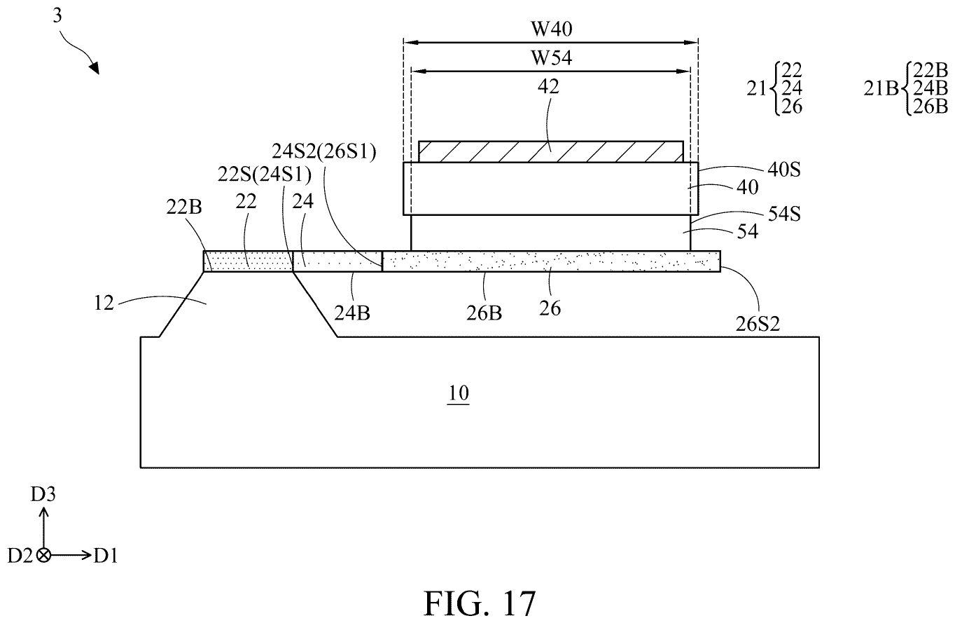

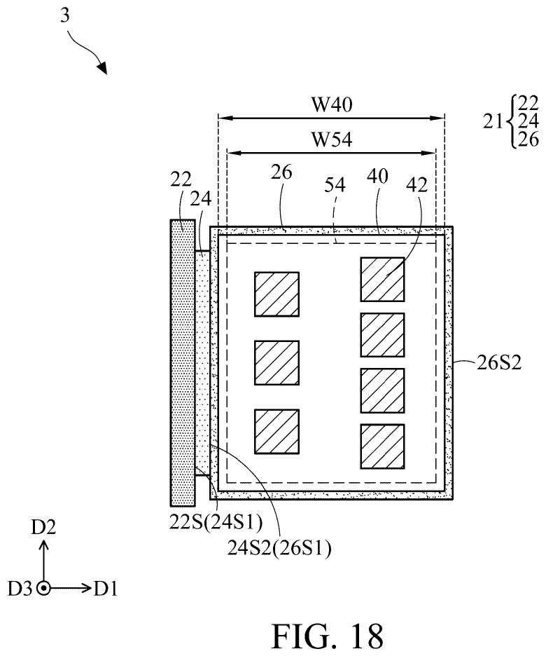

Referring to FIGS. 17 and 18, which are detailed schematic cross-sectional view and partial schematic top view of the semiconductor structure 3 according to some embodiments of the present disclosure. As shown in FIGS. 17 and 18, in some embodiments, the second adhesive layer 54 may be located between the carrying portion 26 of the supporting member 21 and the device layer 40. In some embodiments, in the first direction D1, the width W54 of the second adhesive layer 54 may be smaller than the width W40 of the device layer 40.

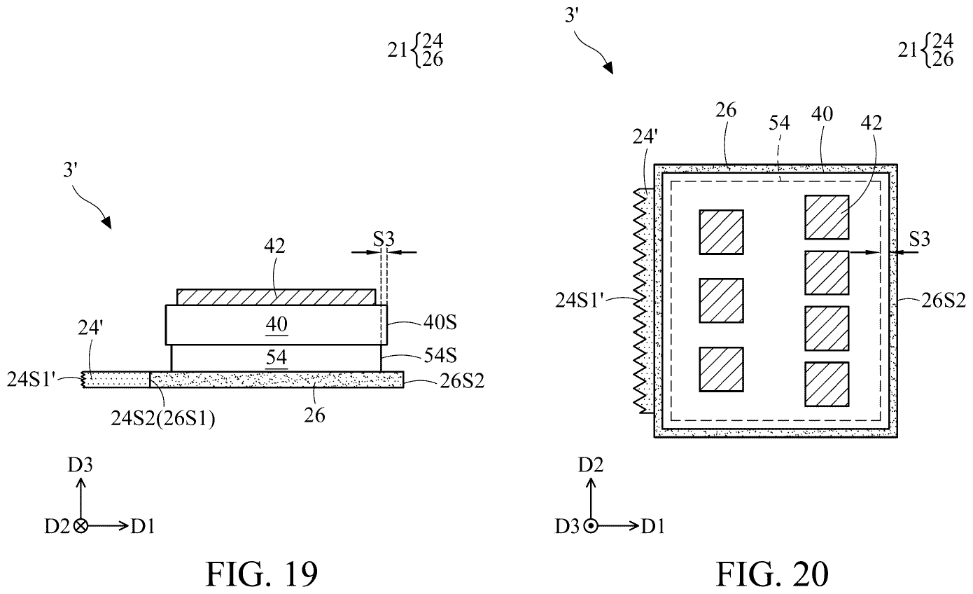

Referring to FIGS. 19 and 20, which are schematic cross-sectional view and schematic top view of the semiconductor unit 3′ according to some embodiments of the present disclosure. In some embodiments, a separation process may be performed on the semiconductor structure 3 to obtain the semiconductor unit 3′. As shown in FIGS. 19 and 20, in some embodiments, the second adhesive layer 54 may be located between the carrying portion 26 of the supporting member 21 and the device layer 40. In some embodiments, in the first direction D1, a third distance S3 may be provided between the side surface 54S of the second adhesive layer 54 and the side surface 40S of the device layer 40. In some embodiments, the third distance S3 may be greater than 0.

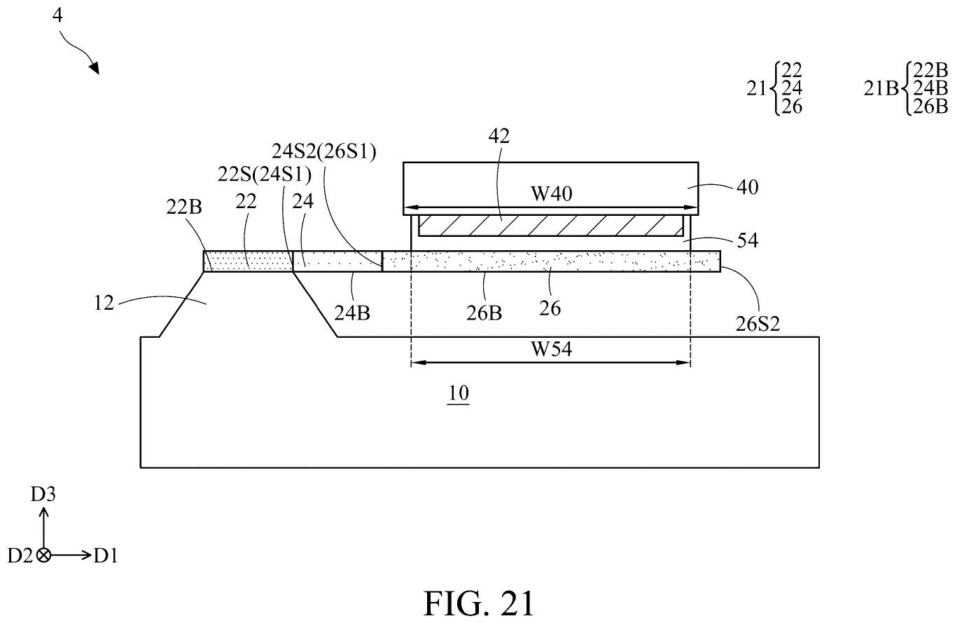

Referring to FIG. 21, it is a schematic cross-sectional view of the semiconductor structure 4 according to some embodiments of the present disclosure. In some embodiments, the contact pad 42 may be located between the device layer 40 and the carrying portion 26 of the supporting member 21. In some embodiments, the contact pad 42 and the carrying portion 26 may be separated from each other by a second adhesive layer 54. In some embodiments, the contact pad 42 may be embedded in the second adhesive layer 54.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an underlying layer having a protruding portion;
a supporting member disposed on the underlying layer and comprising:
a bonding portion connecting to the protruding portion of the underlying layer;
a connecting portion located next to the bonding portion; and
a carrying portion located next to the connecting portion; and
a semiconductor device disposed on the carrying portion and exposing the bonding portion and the connecting portion,
wherein, there is a gap between the carrying portion of the supporting member and the underlying layer.

2. The semiconductor structure as claimed in claim 1, wherein the semiconductor device exposes a portion of the carrying portion and a thickness of the portion of the carrying portion exposed by the semiconductor device is less than a thickness of the carrying portion where the semiconductor device is disposed.

3. The semiconductor structure as claimed in claim 1, wherein the underlying layer comprise silicon or III-V semiconductor material.

4. The semiconductor structure as claimed in claim 1, wherein the semiconductor device comprises:
a semiconductor layer and a device layer, wherein the semiconductor layer is disposed between the carrying portion and the device layer.

5. The semiconductor structure as claimed in claim 4, wherein the underlying layer and the semiconductor layer have the same material.

6. The semiconductor structure as claimed in claim 1, wherein in a top view, the connecting portion has a recess located at an edge of the connecting portion.

7. The semiconductor structure as claimed in claim 1, further comprising:
an adhesive layer disposed between the carrying portion and the semiconductor device.

8. The semiconductor structure as claimed in claim 7, wherein a width of the adhesive layer is less than a width of the semiconductor device.

9. The semiconductor structure as claimed in claim 7, wherein the semiconductor device comprises a III-V semiconductor material.

10. The semiconductor structure as claimed in claim 1, further comprising:
a contact pad disposed between the semiconductor device and the supporting member.

11. The semiconductor structure as claimed in claim 1, further comprising:
a contact pad disposed on the semiconductor device.

12. A semiconductor unit, comprising:
a supporting member comprising:
a connecting portion having a first side surface; and
a carrying portion located next to the connecting portion and having a second side surface; and
a semiconductor device disposed on the carrying portion and exposing the connecting portion,
wherein, a roughness of the first side surface is greater than a roughness of the second side surface.

13. The semiconductor unit as claimed in claim 12, wherein the semiconductor device comprises:
a semiconductor layer and a device layer, wherein the semiconductor layer is disposed between the carrying portion and the device layer, and a side surface of the semiconductor layer is aligned with a side surface of the device layer.

14. The semiconductor unit as claimed in claim 12, further comprising:
an adhesive layer disposed between the carrying portion and the semiconductor device, and there is a distance between a side surface of the adhesive layer and a side surface of the semiconductor device.

15. A method for forming a semiconductor structure, comprising:
providing an underlying layer;
forming an insulating layer on the underlying layer;
forming a semiconductor device on the insulating layer;
patterning the insulating layer to form a supporting member; and
removing a portion of the underlying layer so that there is a gap between a bottom surface of the supporting member and a top surface of the underlying layer.

16. The method as claimed in claim 15, wherein the step of forming the semiconductor device on the insulating layer further comprises:
forming a semiconductor layer on the insulating layer;
forming a device layer on the semiconductor layer; and
removing a portion of the device layer and a portion of the semiconductor layer to expose the insulating layer.

17. The method as claimed in claim 16, wherein the step of removing the portion of the device layer and the portion of the semiconductor layer further comprises:
removing a portion of the insulating layer so that a thickness of the insulating layer covered by the semiconductor layer is greater than a thickness of the insulating layer not covered by the semiconductor layer.

18. The method as claimed in claim 15, wherein the step of patterning the insulating layer further comprises:
forming a recess in the insulating layer.

19. The method as claimed in claim 15, wherein the step of forming the semiconductor device on the insulating layer further comprises:
providing a carrier;
forming a first adhesive layer on the carrier;
forming the semiconductor device on the first adhesive layer;
forming a second adhesive layer to bond the semiconductor device with the insulating layer;
removing the carrier; and
patterning the second adhesive layer.

20. The method as claimed in claim 19, wherein the carrier is removed by irradiating the first adhesive layer and the second adhesive layer with a same laser.
